(19) United States
(12) Patent Application Publication
(10) Pub. No.: US 2023/0146452 A1
(43) Pub. Date: May 11, 2023

(54) METHOD AND APPARATUS FOR MODELING AND FORMING FIBER-REINFORCED COMPOSITE OBJECTS

(71) Applicant: 9T LABS AG, Zürich (CH)

(72) Inventors: Alex LUIJTEN, Zürich (CH); Przemyslaw ZDROIK, Basel (CH); Chester HOUWINK, Zürich (CH); Martin EICHENHOFER, Zürich (CH); Giovanni CAVOLINA, Zürich (CH)

(73) Assignee: 9T LABS AG, Zürich (CH)

(21) Appl. No.: 17/907,899

(22) PCT Filed: Mar. 4, 2021
(86) PCT No.: PCT/IB2021/051836

§ 371 Date: Aug. 29, 2022

(30) Foreign Application Priority Data
Mar. 4, 2020 (WO) PCT/IB2020/051893
Mar. 5, 2020 (WO) PCT/IB2020/051923
Jan. 4, 2021 (WO) PCT/IB2021/050016
Mar. 4, 2021 (WO) PCT/IB2021/051825

(51) Int. Cl. B29C 64/393; G05B 19/4099; B33Y 50/02

(52) U.S. Cl. CPC B29C 64/393; G05B 19/4099; B33Y 50/02; G05B 2219/35134

(57) ABSTRACT

A computer-implemented method comprising, under the control of one or more computer systems or non-volatile storage medium configured with executable instructions: acquiring a digital model comprising two or more spatial dimensions of an object to be manufactured; forming a three-dimensional model decomposition of the object to be manufactured, wherein forming the three-dimensional model decomposition comprises segmenting at least a portion of the digital model comprising two or more spatial dimensions into one or more surface-based component models; and forming, on one or more surfaces of the one or more surface-based component models, one or more paths comprising one or more elongate fiber tow models.

### FIELD

The present invention relates to systems and methods for modeling and forming fiber-reinforced plastic composite objects comprising one or more fiber tows.

### BACKGROUND

Fiber-reinforced plastics (FRP), also called fiber-reinforced polymers, for example carbon fiber-reinforced plastics (CFRP) are widely used materials for lightweight structures, ranging from sports equipment, to automotive components, to aircraft structures. A method for manufacturing of FRP's comprises depositing fiber tows, for example preimpregnated fiber tows.

Forming of fiber-reinforced plastic composite objects is, for example, accomplished with robots to deposit layers of fiber material. Given a design, for example a three-dimensional model of an object to manufacture, raises the problem of how to manufacture the object using a plurality of layers of fiber material, for example using a robotic system. There is therefore a need for a system to assist a user with the analysis of an object to be manufactured using a plurality of fiber layers, to decompose the object into manufacturable components, to plan the paths of a robot that will deposit a plurality of fiber layers to form the components, and to prepare commands for guiding a robot to deposit the fiber layers. Although solutions exist for manufacturing of objects using flat fiber tapes, there is a need for solutions for analyzing, segmenting, and manufacturing objects using fiber tows which are substantially narrower and thicker than fiber tapes. There is also a need for systems and methods to to plan the application of fiber tows onto a surface to form an object. There is also a need to lay fiber tows over trajectories that comprise curves with small radii of curvature, and with improved and diversified fiber layout patterning capabilities. There is also a need for systems and methods to forecast and adjust a design for a compression molding step that, for example, introduces distortions in an object and the paths of the fiber material from which the object is made.

### SUMMARY

This disclosure presents methods and systems for designing, segmenting, planning, and forming fiber-reinforced plastic composite objects. For example, the fiber-reinforced plastic composite objects comprise elongate fiber tows, for example elongate carbon fiber tows. For example, the fiber tows, because they are narrow, can be formed into tight curves. A method for forming tight curves using an elongate fiber tow comprises, for example, one or more of depositing the tow onto the surface of an object using a pressure foot device and forming a twist in the tow. For example, the pressure foot device is rotatable around an axis, for example an axis orthogonal to the surface of the object. The method for forming tight curves comprises, for example, rotating the pressure foot device that comprises a groove for one or more of guiding and rotating the tow onto the surface of an object.

FIG. 5 is a block diagram of a method for modeling and forming fiber-reinforced objects. The method is, for example, a computer-implemented method. The computer-implemented method is, for example, stored as computer-readable instructions on a non-transitory computer-readable storage medium. For example, the computer-implemented method, comprises, under the control of one or more computer systems configured with executable instructions: acquiring a digital model comprising two or more spatial dimensions of an object to be manufactured; forming a three-dimensional model decomposition of the object to be manufactured, wherein forming the three-dimensional model decomposition comprises segmenting at least a portion of the digital model comprising two or more spatial dimensions into one or more surface-based component models; and forming, on one or more surfaces of the one or more surface-based component models, one or more paths comprising one or more elongate fiber tow models.

For example, an embodiment of a surface-based component is planar. For example, an embodiment of a surface-based component is an isotropic deformation of a planar sheet, for example curved into one or more of a cylinder, a cylinder sector, a U, a V, a parabola, a wave. For example, the surface-based component is an isotropic deformation a planar sheet having undergone further anisotropic deformation that comprises one or more of stretching, compressing, and double-curvature bending in an additional range of, for example, up to 20% of the isotropic deformation of the planar sheet.

For example, one or more of the one or more elongate fiber tow models is formed of one or more longitudinally-folded fiber tape models. For example, one or more of the one or more elongate fiber tow models comprises a rectangular cross-section. For example, one or more of the one or more elongate fiber tow models comprises a width 100W comprised in a range from 0.2 mm to 4 mm, for example from 0.4 mm to 2 mm. For example, one or more of the one or more elongate fiber tow models further comprises a height comprised in a range from 0.03 mm to 0.5 mm, for example from 0.12 mm to 0.25 mm.

For example, forming one or more paths comprises forming one or more concentric paths that are concentrically adjacent to each other. For example, forming one or more paths comprises forming one or more contour paths that follow at least a portion of a contour of one or more of the one or more surface-based component models; and forming a first layer comprising a first plurality of parallel paths and forming a second layer comprising a second plurality of parallel paths, wherein the second layer overlaps the first layer and the paths in the second layer are orthogonal to the paths in the first layer; and wherein the area covered by the first layer and the second layer is at least partially bounded by the one or more contour paths.

For example, forming one or more paths comprises acquiring a value for a number of layers of paths to form. For example, forming one or more paths comprises acquiring a value for a number of coplanar adjacent paths to form. For example, forming one or more paths comprises adjusting a spread of two or more coplanar adjacent paths to form. For example, forming one or more paths comprises acquiring a value for adjusting a spread of two or more coplanar adjacent paths to form over a selected region comprising one or more dimensions. For example, forming one or more paths comprises acquiring a value for a minimum longitudinal tow extremity offset from a surface-based component's contour.

For example, forming one or more paths comprises actuating a tow cutter as a function of one or more of a minimum tow extremity longitudinal offset from a surface-based component's contour, a path extremity longitudinal distance from a surface-based component's contour, and a lower limit on the tow length.

For example, forming one or more paths comprises forming one or more adjacently concentric spiral paths. For example, an adjacently concentric spiral comprises a spiral path comprising one or more tows that are adjacent along their longitudinal side. For example, a tow in a spiral path is longitudinally adjacent to itself upon completing one or more loops. In some embodiments, a filler, for example comprising a thermoplastic material, is formed between the tows forming the loops of the spiral path.

For example, forming one or more paths comprises forming one or more concentric contour paths that follow at least a portion of a contour of one or more of the one or more surface-based component models. For example, forming one or more paths comprises forming one or more contour paths at one or more offsets from a contour of one or more of the one or more surface-based component models.

For example, the method comprises acquiring path instructions comprised in a path pattern library. For example, the path pattern library comprises forming one or more of: a rectangular path pattern; a rounded rectangular path pattern; a circular path pattern; and a figure of eight path pattern. For example, forming one or more paths comprises forming one or more path patterns selected from a path pattern library.

For example, forming one or more paths comprises defining one or more regions of interest 16108 comprising one or more dimensions X, Y, Z and wherein the one or more regions of interest are highlighted on a computer display presenting one or more views of the surface-based components. For example, forming one or more paths comprises forming one or more path patterns selected from a path pattern library at one or more offsets from the one or more regions of interest.

For example, the method comprises acquiring a digital model of the object to be manufactured comprises storing in computer memory forbidden regions wherein the forming of paths comprising one or more elongate fiber tow models is excluded. For example, the method comprises highlighting, on a computer display presenting one or more views of the surface-based components, one or more of the forbidden regions. For example, the acquired digital model of the object to be manufactured comprises designated forbidden regions wherein the forming of paths comprising one or more elongate fiber tow models is excluded.

For example, forming of one or more paths comprising one or more elongate fiber tow models comprises a lower limit on the tow length. For example, forming one or more paths comprising one or more elongate fiber tow models comprises instructions to read from memory a lower limit on the tow length. For example, the method comprises highlighting, on a computer display presenting one or more views of: one or more of the surface-based components; one or more of the paths; and one or more of the elongate fiber tow models; wherein one or more of the elongate fiber tows the length of which is less than the lower limit on the tow length.

For example, forming one or more path comprising one or more elongate fiber tow model comprises reading from a computer memory a lower limit on the radius of curvature of the paths wherein a fiber tow follows the path continuously. For example, the method comprises highlighting, on a computer display presenting one or more view of the surface-based components, one or more of the tow path wherein the radius of curvature is lower than the radius of curvature lower limit stored in memory.

For example, forming one or more paths comprising one or more elongate fiber tow models comprises instructions to store in memory the tow twist at one or more locations along the path. For example, the method comprises highlighting, on a computer display presenting one or more views of the surface-based components, one or more of the tow paths wherein the tow twist is greater than a tow twist threshold stored in memory.

For example, forming of one or more paths comprising one or more elongate fiber tow models comprises a lower limit on the radius of curvature of the paths wherein a fiber tow follows the path continuously. For example, forming of one or more paths comprising one or more elongate fiber tow models comprises recording the tow twist at one or more locations along the path. For example, forming of one or more paths comprising one or more elongate fiber tow models comprises forming a discontinuity in the fiber tow at one or more locations in the path comprising a radius of curvature that is less than a lower limit. For example, forming of one or more paths comprises actuating a tow cutter 2300.

For example, forming of one or more path comprising one or more elongate fiber tow model comprises forming one or more dimensional value of tow-free space enclosed by one or more path. For example, the one or more dimensional value of tow-free space is estimated, for example using a computation on a processor, in 2 or 3 spatial dimensions. For example, an alarm is raised, for example visually on a display, for example as a highlight projected onto the model, if one or more tow-free space value is greater than a predefined threshold, for example stored in memory. For example, if a value of tow-free space is greater than a tow-free space threshold value, one or more reinforcing path is formed within the tow-free space.

For example, forming of one or more path comprising one or more elongate fiber tow model comprises forming along the path one or more value of tow-free distance to one or more path around one or more of the path's centerline and the path's edge. For example, if a value of tow-free distance is greater than a tow-free distance threshold value, one or more waypoint defining the one or more path is adjusted to decrease the tow-free distance of the one or more path. For example, if a value of tow-free distance is greater than a tow-free distance threshold value, adjusting one or more waypoint defining the one or more path to decrease the tow-free distance of the one or more path. For example, the method comprises highlighting, on a computer display presenting one or more view of the surface-based components, one or more of the tow path wherein the tow-free distance is greater than a tow-free distance threshold stored in a computer memory.

For example, forming of one or more path comprising one or more elongate fiber tow model comprises forming a plurality of parallel paths that are spaced apart by a distribution profile specified by one or more distribution component. For example, the distribution profile comprises one or more of a ramp, an ellipse, a parabola, a hyperbola, and a curve specified using a user-edited function.

For example, segmenting the digital model comprises forming a first surface-based component comprising a first half-joint comprising one or more of a tenon and a mortise and forming a second surface-based component comprising a second half-joint matching the first half-joint and comprising one or more of a mortise and a tenon. For example, segmenting the digital model comprises: forming a first surface-based component and forming a second surface-based component that forms a joining between the first surface-based component, wherein one or more of the first surface-based component and the second surface-based component comprises one or more fillet at the joining between the first surface-based component and the second surface-based component. For example, segmenting the digital model comprises forming a first surface-based component and forming a second surface-based component that forms a joining between the first surface-based component at a joining region, and wherein the forming one or more path model comprises forming on the second surface-based component, at the joining region, one or more path that forms an angle of at most 80°, for example at most 60°, with a normal to the first surface-based component at the joining region.

For example, the method comprises acquiring one or more axis of symmetry in one or more of the surface-based components and dividing the one or more of the surface-based components at the one or more axes of symmetry into a plurality of component regions; and wherein the forming one or more path models comprises forming one or more first path model into a first component region of the plurality of component regions and mirroring the first path model into one or more of the other component regions of the plurality of component regions.

For example, the method comprises highlighting, on a computer display presenting one or more view of the surface-based component, one or more of the component region. For example, the method comprises highlighting, on a computer display presenting one or more view of the surface-based component, one or more axis of symmetry in one or more of the surface-based component.

For example, forming a three-dimensional model decomposition comprises enlarging one or more of the one or more surface-based component in one or more direction. For example, the method comprises a step of simulating a step comprising one or more of heating and compressing an assembly comprising one or more surface-based component models comprising one or more elongate fiber tow. For example, the simulating step comprises simulating a compression molding step. For example, the simulating step comprises forming one or more of a heating simulation and a compression simulation and rendering its results on a computer display. For example, the simulating step comprises estimating a decrease in size in one or more direction of one or more of the one or more surface-based components. For example, the simulating step comprises deforming one or more of the one or more surface-based components in one or more three-dimensional direction at one or more surface location. For example, the simulating step comprises forming instructions to adjust a computer-controlled compression molding process. For example, the simulating step comprises simulating a flow of infill material. For example, the simulating step comprises estimating a decrease in size in one or more dimension of one or more region comprising infill material. For example, the simulating step comprises estimating the displacement in one or more dimension of one or more path. For example, the simulating step comprises estimating the displacement in one or more dimensions of one or more elongate tow. For example, the simulating step comprises highlighting, on a computer display presenting one or more view of the surface-based components, one or more region wherein a displacement of infill material is greater than an an infill displacement threshold stored in memory.

For example, forming one or more path comprises forming one or more command to rotate a pressure foot device. For example, forming one or more path comprises forming one or more command to rotate a pressure foot device to an orientation angle with respect to a local tangent to the path being formed. For example, forming one or more path comprises actuating one or more pinch roller.

The disclosure also presents a system comprising: one or more computer processor; and memory with executable instructions that, when executed by the one or more processor, cause the system to: receive a digital model comprising two or more spatial dimensions of an object to be manufactured; form a three-dimensional model decomposition of the object to be manufactured, wherein forming the three-dimensional model decomposition comprises segmenting at least a portion of the digital model comprising two or more spatial dimensions into one or more surface-based component; and form, on a surface of the one or more surface-based component model, one or more path comprising one or more elongate fiber tow model. For example, one or more of the one or more elongate fiber tow model is formed of one or more longitudinally-folded fiber tape model.

For example, the system comprises an apparatus comprising a pressure foot device comprising a channel for guiding an elongate fiber tow onto an object surface. For example, the channel comprises a groove. For example, the pressure foot device is coupled to a pressure foot device rotation actuator. For example, the pressure foot device is comprised in a foot shaft housing 2100, characterized by a pressure foot device's axis of rotation Z, defining a Z-axis, wherein the pressure foot device's axis of rotation Z is collinear with the channel for guiding an elongate fiber tow onto an object surface.

For example, the system comprises a computer display. For example, the system comprises a communication network connected to a system for applying an elongate fiber tow. For example, the system comprises a communication network connected to a computer server comprising a non-volatile storage medium comprising instructions describing one or more of: one or more digital model comprising two or more spatial dimensions of one or more object to be manufactured; one or more plane-based component; and one or more path. For example, one or more of the system and the computer server one or more of receive and transmit data indicating the status of the system and the state of an object being manufactured.

The disclosure also presents a non-transitory computer-readable storage medium comprising executable instructions that, when executed by one or more processor of a computer system, cause the computer system to at least: acquire a digital model comprising two or more spatial dimensions of an object to be manufactured; form a three-dimensional model decomposition of the object to be manufactured, wherein forming the three-dimensional model decomposition comprises segmenting at least a portion of the digital model comprising two or more spatial dimensions into one or more surface-based component; and form, on a surface of the one or more surface-based component model, one or more paths comprising one or more elongate fiber tow model.

For example, the instructions to form one or more path further comprise instructions to execute one or more of forming, loading, and storing into memory one or more elongate fiber tow model formed of one or more longitudinally-folded fiber tape model. For example, the elongate fiber tow model is a digital model, for example comprised in a digital library, for example stored on a non-transitory computer-readable storage medium. For example, one or more of the one or more elongate fiber tow model comprises a rectangular cross-section. For example, one or more of the one or more elongate fiber tow model comprises a width comprised in a range from 0.2 mm to 4 mm, for example from 0.4 mm to 2 mm. For example, one or more of the one or more elongate fiber tow models further comprises a height comprised in a range from 0.03 mm to 0.5 mm, for example from 0.12 mm to 0.25 mm.

For example, the instructions to form one or more path comprises instructions to form one or more set of concentric paths that are concentrically adjacent to each other. For example, the instructions to form one or more paths comprise instructions to: form one or more contour paths that follow at least a portion of a contour of one or more of the one or more surface-based component model; and form a first layer comprising a first plurality of parallel paths and form a second layer comprising a second plurality of parallel paths, wherein the second layer overlaps the first layer and the paths in the second layer are orthogonal to the paths in the first layer; and wherein the area covered by the first layer and the second layer is at least partially bounded by the one or more contour path. For example, the instructions to form one or more path comprise instructions to acquire a value for a number of layers of paths to form. For example, the instructions to form one or more path comprise instructions to acquire a value for a number of coplanar adjacent paths to form. For example, the instructions to form one or more path comprise instructions for adjusting a spread of two or more coplanar adjacent paths to form.

For example, the instructions to form one or more paths comprise instructions to acquire a value for adjusting a spread of two or more coplanar adjacent paths to form over a selected region comprising one or more spatial dimensions. For example, the instructions to form one or more paths comprise instructions to acquire a value for a minimum longitudinal tow extremity offset from a surface-based component's contour.

For example, the instructions to form one or more paths comprise instructions to actuate a tow cutter as a function of one or more of a minimum tow extremity longitudinal offset from a surface-based component's contour, a path extremity longitudinal distance from a surface-based component's contour, and a lower limit on the tow length.

For example, the instructions to form one or more paths comprise instructions to form one or more adjacently concentric spiral paths. For example, the instructions to form one or more paths comprise instructions to form one or more concentric contour paths that follow at least a portion of a contour of one or more of the one or more surface-based component models. For example, the instructions to form one or more paths comprise instructions to form one or more contour paths at one or more offsets specified in one or more directions from a contour of one or more of the one or more surface-based component models.

For example, the instructions further comprise instructions to acquire path instructions comprised in a path pattern library. For example the path pattern library is stored on a non-volatile storage medium. For example, the instructions comprised in the path pattern library comprise instructions to form one or more of: a rectangular path; a rounded rectangular path; a circular path; and a figure of eight path 7801. For example, the instructions to form one or more paths comprise instructions to form one or more path patterns selected from a path pattern library.

For example, the instructions to form one or more paths comprise instructions to define one or more regions of interest comprising one or more dimensions and wherein the one or more regions of interest are highlighted on a computer display presenting one or more views of the surface-based components. For example, the instructions to form one or more paths comprise instructions to form one or more path patterns selected from a path pattern library at one or more offsets from the one or more regions of interest.

For example, the instructions to acquire a digital model of the object to be manufactured comprise instructions to store in memory one or more forbidden region wherein the forming of paths comprising one or more elongate fiber tow models is excluded. For example, the instructions to acquire a digital model of the object to be manufactured comprise instructions to highlight, on a computer display presenting one or more views of the surface-based components, one or more of the forbidden region.

For example, the instructions to form one or more path comprising one or more elongate fiber tow model comprise instructions to read from memory a lower limit on the tow length. For example, the instructions comprise instructions to highlight, on a computer display presenting one or more view of: one or more of the surface-based components; one or more of the paths; and one or more of the elongate fiber tow models; wherein one or more of the elongate fiber tows the length of which is less than the lower limit on the tow length.

For example, the instructions to form one or more path comprising one or more elongate fiber tow model comprise instructions to read from memory a lower limit on the radius of curvature of the paths wherein a fiber tow follows the path continuously. For example, the instructions comprise instructions to highlight, on a computer display presenting one or more view of the surface-based components, one or more of the tow paths wherein the radius of curvature is lower than the radius of curvature lower limit stored in memory.

For example, the instructions to form one or more path comprising one or more elongate fiber tow model comprise instructions to store in memory the tow twist at one or more location along the path. For example the instructions comprise instructions to highlight, on a computer display presenting one or more views of the surface-based components, one or more of the tow paths wherein the tow twist is greater than a tow twist threshold stored in memory.

For example, the instructions to form one or more path comprising one or more elongate fiber tow model comprise instructions to form a discontinuity in the fiber tow at one or more location in the path comprising a radius of curvature that is less than a lower limit. For example, the instructions to form one or more paths comprise instructions to actuate a tow cutter.

For example, the instructions to form one or more path comprising one or more elongate fiber tow model comprise instructions to form one or more dimensional value of tow-free space enclosed by one or more path. For example, the instructions comprise instructions wherein if a value of tow-free space is greater than a tow-free space threshold value, instructions are provided to form one or more reinforcing path within the tow-free space.

For example, the instructions to form one or more path comprising one or more elongate fiber tow model comprise instructions to form along the path and store in memory one or more value of tow-free distance to one or more path around one or more of the path's centerline and the path's edge. For example, the instructions comprise instructions wherein if a value of tow-free distance is greater than a tow-free distance threshold value, instructions are provided to adjust one or more waypoint defining the one or more path to decrease the tow-free distance of the one or more path. For example, the instructions comprise instructions to highlight, on a computer display presenting one or more view of the surface-based components, one or more of the tow paths wherein the tow-free distance is greater than a tow-free distance threshold stored in memory.

For example, the instructions to form one or more path comprising one or more elongate fiber tow model comprise instructions to form a plurality of parallel paths that are spaced apart by a distribution profile specified by reading from memory one or more distribution component.

For example, the instructions to segment the digital model comprise instructions to form a first surface-based component comprising a first half-joint comprising one or more of a tenon and a mortise and to form a second surface-based component comprising a second half-joint matching the first half-joint and comprising one or more of a mortise and a tenon. For example, instructions to segment the digital model comprise instructions to form a first surface-based component and to form a second surface-based component that forms a joining between the first surface-based component, wherein one or more of the first surface-based component and the second surface-based component comprises one or more fillets at the joining between the first surface-based component and the second surface-based component. For example, the instructions to segment the digital model comprise instructions to form a first surface-based component and form a second surface-based component that forms a joining between the first surface-based component and the second surface-based component at a joining region 17000J, and wherein the instructions to form one or more path models 7001, 7002, 7003, 100PC, 10201, 10202, 10203, 10204, 10205 comprise instructions to form on the second surface-based component, at the joining region, paths that form an angle of at most 80°, for example at most 60°, with a normal to the first surface-based component at the joining region.

For example, the instructions comprise instructions to acquire one or more axis of symmetry in one or more of the surface-based component and to divide the one or more of the surface-based component at the one or more axis of symmetry into a plurality of component regions; and wherein the instructions to form one or more path model comprises instructions to form one or more first path model into a first component region of the plurality of component regions and instructions to mirror the first path model into one or more of the other component regions of the plurality of component regions. For example the instructions comprise instructions to highlight, on a computer display presenting one or more view of the surface-based components, one or more of the component region.

For example, the instructions comprise instructions to highlight, on a computer display presenting one or more view of the surface-based components, one or more axis of symmetry in one or more of the surface-based components.

For example, the instructions to form a three-dimensional model decomposition comprise instruction to enlarge one or more of the one or more surface-based components in one or more direction.

For example, the instructions comprise instructions to simulate a step comprising one or more of heating and compressing an assembly comprising one or more surface-based component model comprising one or more elongate fiber tow. For example, the instructions for the simulation step comprise instructions to estimate a decrease in size in one or more direction of one or more of the one or more surface-based components. For example, the instructions for the simulation step comprise instructions to deform one or more of the one or more surface-based components in one or more three-dimensional direction at one or more surface location. For example, the instructions for the simulation step comprise forming instructions to adjust a computer-controlled compression molding process. For example, the instructions to adjust a computer-controlled compression molding process comprise instructions to adjust one or more of compression rate and compression temperature. For example, the instructions for the simulation step comprise instructions to simulate a flow of infill material. For example, the instructions for the simulation step comprise instructions to estimate a decrease in size in one or more dimension of one or more region comprising infill material. For example, the instructions for the simulation step comprise instructions to estimate the displacement in one or more dimensions of one or more path. For example, the instructions for the simulation step comprise instructions to estimate the displacement in one or more dimension of one or more elongate tow. For example, the instructions comprise instructions to highlight, on a computer display presenting one or more view of the surface-based components, one or more region wherein a displacement of infill material is greater than an an infill displacement threshold stored in memory.

For example, the instructions to form one or more path comprise instructions to form one or more command to rotate a pressure foot device. For example, the instructions to form one or more path comprise instructions to form one or more command to rotate a pressure foot device to an orientation angle with respect to a local tangent to the path being formed. For example, the instructions to form one or more path comprise instructions to actuate one or more pinch roller.

### BRIEF DESCRIPTION OF DRAWINGS

FIG. 1 is a block diagram for an apparatus for modeling and forming fiber-reinforced objects.

FIG. 2A is a perspective view of a system for applying an elongate fiber tow for forming fiber-reinforced objects.

FIG. 2B is a perspective view of a pressure foot device.

FIG. 3A1 is a perspective view of tow paths of a first surface-based component model for forming a first fiber-reinforced object component.

FIG. 3A2 is a perspective view of tow paths of a first fiber-reinforced object component.

FIG. 3B1 is a perspective view of tow paths of a second surface-based component model for forming a second fiber-reinforced object component.

FIG. 3B2 is a perspective view of tow paths of a second fiber-reinforced object component.

FIG. 3C is a perspective view of an assembly sequence to form a joining by tenon into mortise insertion of a first fiber-reinforced object component into a second fiber-reinforced object component.

FIG. 3D is a perspective view of a fiber-reinforced object comprising a first fiber-reinforced object component and a second fiber-reinforced object component.

FIGS. 4A, 4B, 4C present different embodiments of elongate fiber to models.

FIG. 5 is a block diagram of a method for modeling and forming fiber-reinforced objects.

FIG. 6 is a graphical user interface for a system for modeling and forming fiber-reinforced objects.

FIG. 7 is an embodiment of surface-based component model for forming a fiber-reinforced object component.

FIG. 8A is an exploded perspective view of a fiber-reinforced object comprising a plurality of surface-based components that comprise a tenon and mortise joining and a plurality of fillets.

FIG. 8B is a perspective view of a fiber-reinforced object comprising a tenon and mortise joining and a plurality of fillets.

FIG. 9A is top view of a path for a figure of eight.

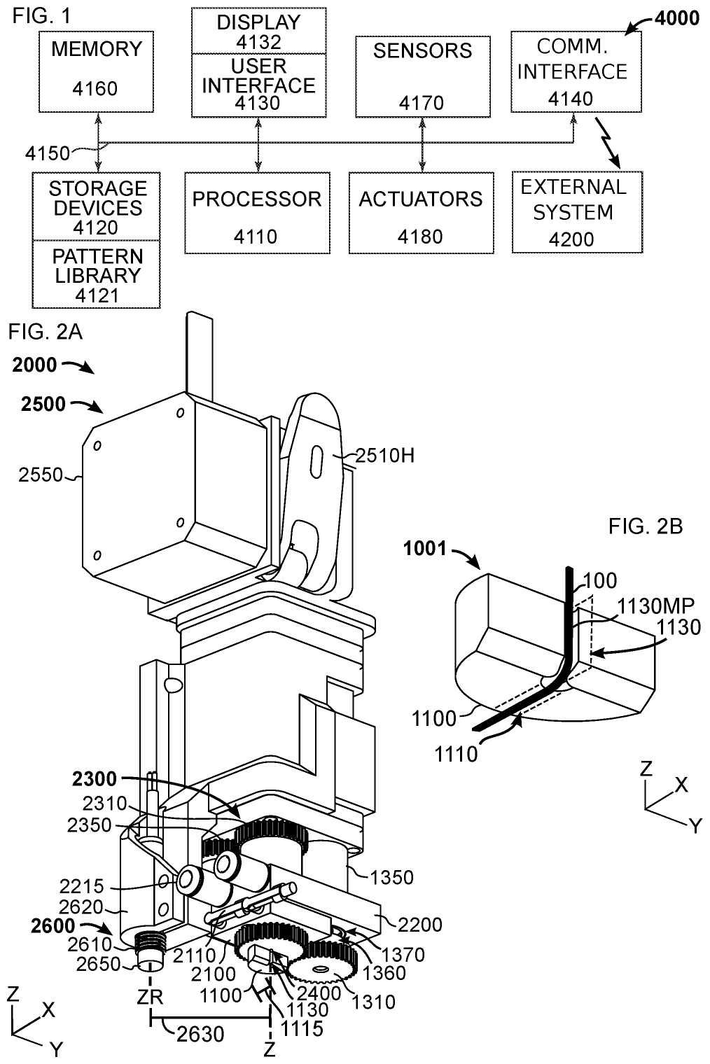

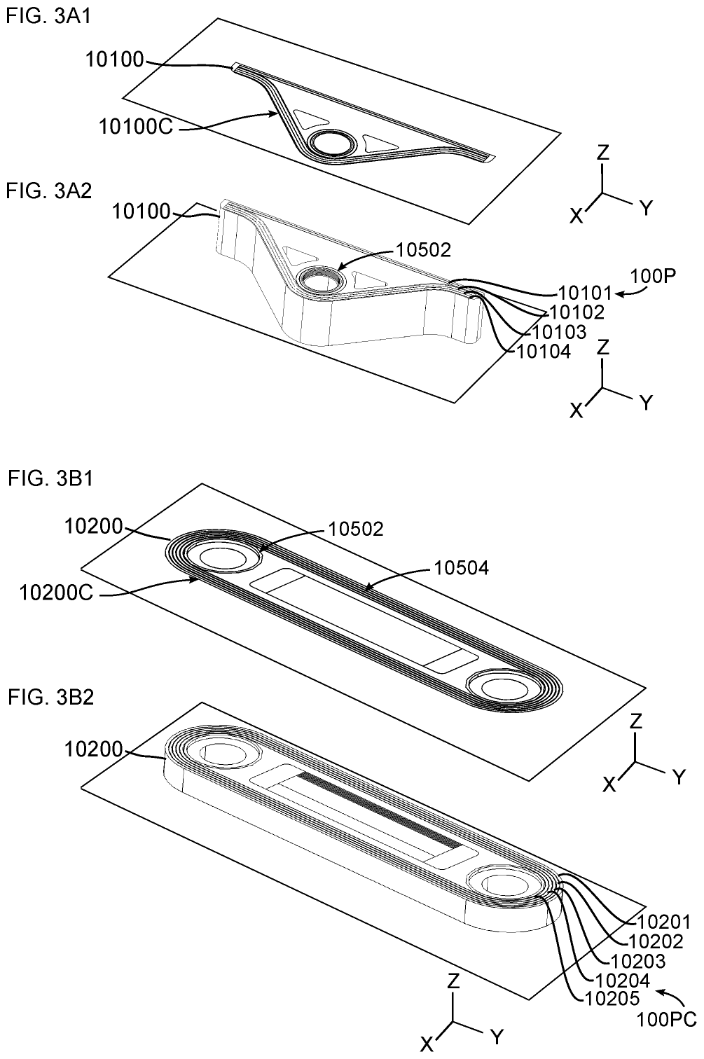

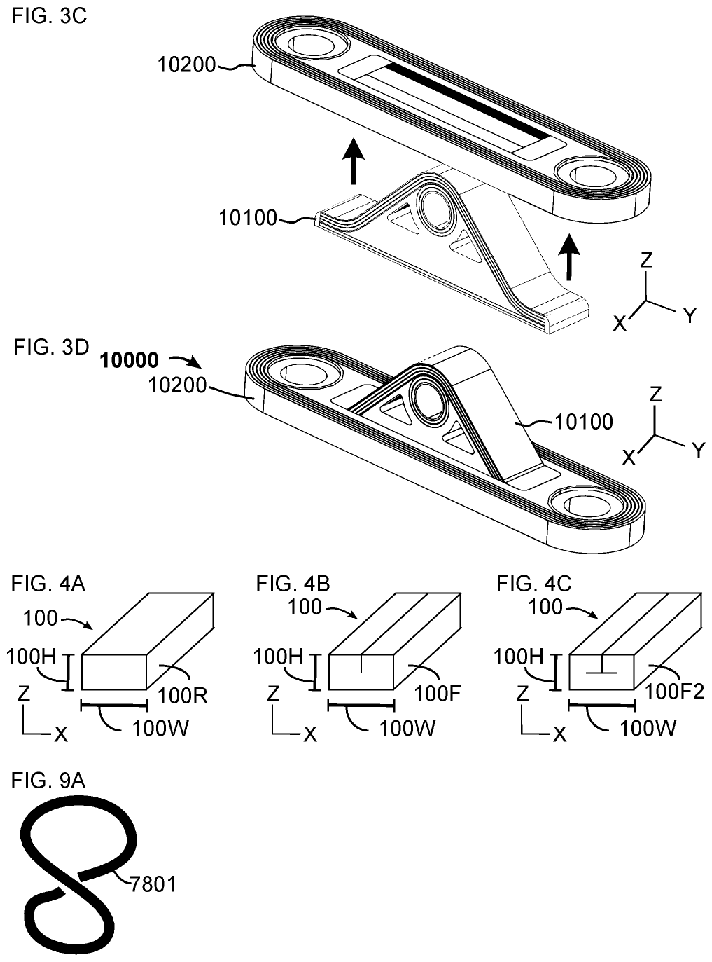

### DESCRIPTION OF EMBODIMENTS

This disclosure presents methods and systems for designing, segmenting, planning, and forming fiber-reinforced plastic composite objects. For example, the fiber-reinforced plastic composite objects comprise elongate fiber tows, for example elongate carbon fiber tows. For example, the fiber tows, because they are narrow, can be formed into tight curves. A method for forming tight curves using an elongate fiber tow comprises, for example, one or more of depositing the tow onto the surface of an object using a pressure foot device and forming a twist in the tow. For example, the pressure foot device is rotatable around an axis, for example an axis orthogonal to the surface of the object. The method for forming tight curves comprises, for example, rotating the pressure foot device that comprises a groove for one or more of guiding and rotating the tow onto the surface of an object.

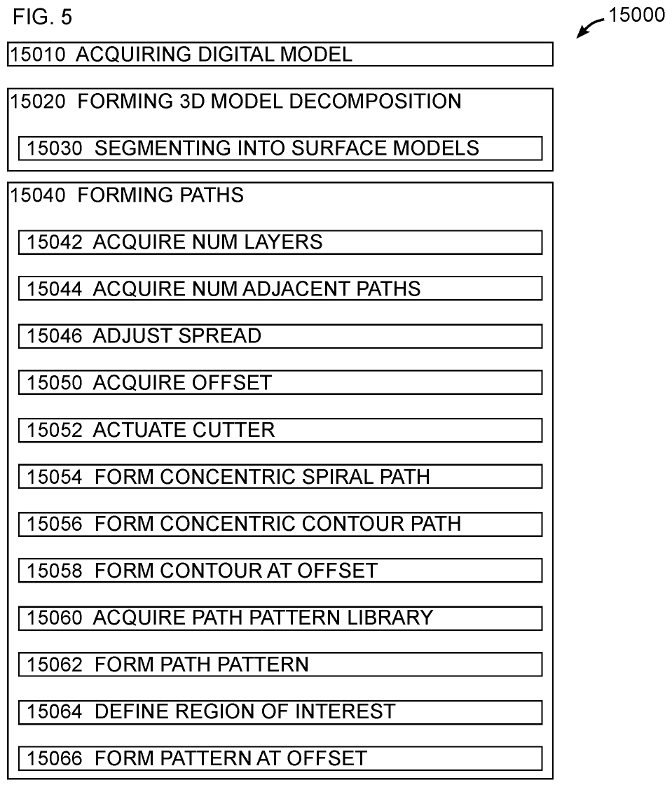

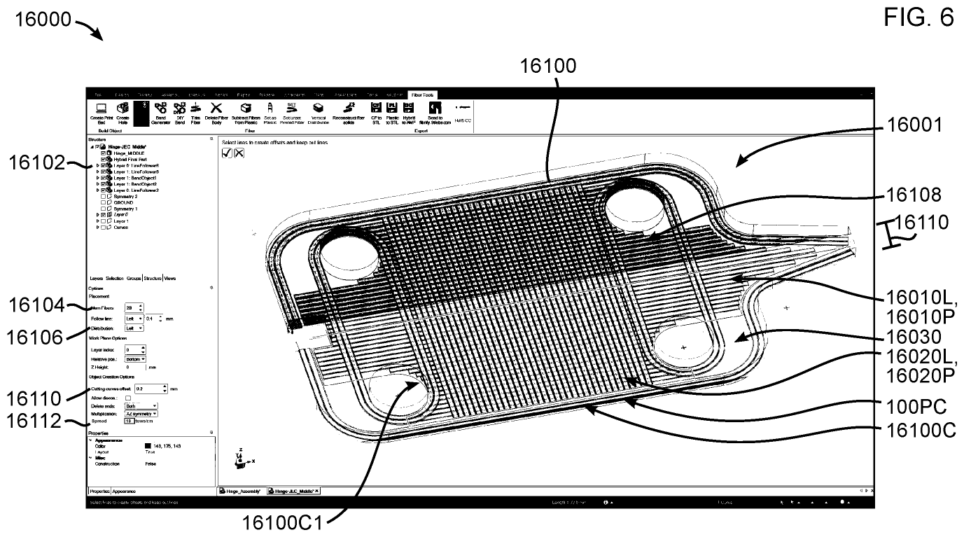

FIG. 5 is a block diagram of a method for modeling and forming fiber-reinforced objects. The method is, for example, a computer implemented method 15000. The computer implement method 15000 is, for example, stored as computer-readable instructions on a non-transitory computer-readable storage medium 4120. For example, the computer-implemented method 15000, comprises, under the control of one or more computer systems 4000 configured with executable instructions: acquiring 15010 a digital model comprising two or more spatial dimensions of an object 10000 to be manufactured; forming 15020 a three-dimensional model decomposition of the object to be manufactured, wherein forming the three-dimensional model decomposition comprises segmenting 15030 at least a portion of the digital model comprising two or more spatial dimensions into one or more surface-based component models 10100, 10200; and forming 15040, on one or more surfaces of the one or more surface-based component models, one or more paths 100P, 100PC, 10101, 10102, 10103, 10104, 10201, 10202, 10203, 10204, 10205 comprising one or more elongate fiber tow models 100, 100R, 100F, 100F2.

For example, an embodiment of a surface-based component is planar. For example, an embodiment of a surface-based component is an isotropic deformation of a planar sheet, for example curved into one or more of a cylinder, a cylinder sector, a U, a V, a parabola, a wave. For example, the surface-based component is an isotropic deformation a planar sheet having undergone further anisotropic deformation that comprises one or more of stretching, compressing, and double-curvature bending in an additional range of, for example, up to 20% of the isotropic deformation of the planar sheet.

For example, one or more of the one or more elongate fiber tow models 100, 100R, 100F, 100F2 is formed of one or more longitudinally-folded fiber tape models 100F, 100F2. For example, one or more of the one or more elongate fiber tow models 100, 100R, 100F, 100F2 comprises a rectangular cross-section. For example, one or more of the one or more elongate fiber tow models 100, 100R, 100F, 100F2 comprises a width 100W comprised in a range from 0.2 mm to 4 mm, for example from 0.4 mm to 2 mm. For example, one or more of the one or more elongate fiber tow models 100, 100R, 100F, 100F2 further comprises a height 100H comprised in a range from 0.03 mm to 0.5 mm, for example from 0.12 mm to 0.25 mm.

For example, forming one or more paths comprises forming one or more concentric paths 100PC, 10201, 10202, 10203, 10204, 10205 that are concentrically adjacent to each other. For example, forming one or more paths 100P, 100PC comprises forming one or more contour paths 100P, 100PC, 10101, 10102, 10103, 10104, 10201, 10202, 10203, 10204, 10205 that follow at least a portion of a contour 10100C, 10200C of one or more of the one or more surface-based component models 10100, 10200; and forming a first layer 16010L comprising a first plurality of parallel paths 16010P and forming a second layer 16020L comprising a second plurality of parallel paths 16020P, wherein the second layer 16020L overlaps the first layer 16010L and the paths 16020P in the second layer 16020L are orthogonal to the paths 16010P in the first layer 16010L; and wherein the area covered by the first layer 16010L and the second layer 16020L is at least partially bounded by the one or more contour paths 100PC.

For example, forming one or more paths 100P, 100PC comprises acquiring 15042 a value for a number of layers 16102 of paths 100P, 100PC to form. For example, forming one or more paths comprises acquiring 15044 a value for a number of coplanar adjacent paths 16104 to form. For example, forming one or more paths comprises adjusting 15046 a spread 16106 of two or more coplanar adjacent paths to form. For example, forming one or more paths comprises acquiring a value for adjusting a spread of two or more coplanar adjacent paths to form over a selected region 16108 comprising one or more dimensions. For example, forming one or more paths comprises acquiring 15050 a value for a minimum longitudinal tow extremity offset 16110 from a surface-based component's contour 16100C1.

For example, forming one or more paths comprises actuating 15052 a tow cutter 2300 as a function of one or more of a minimum tow extremity longitudinal offset 16110 from a surface-based component's contour, a path extremity longitudinal distance from a surface-based component's contour 16100C, and a lower limit on the tow length 2341.

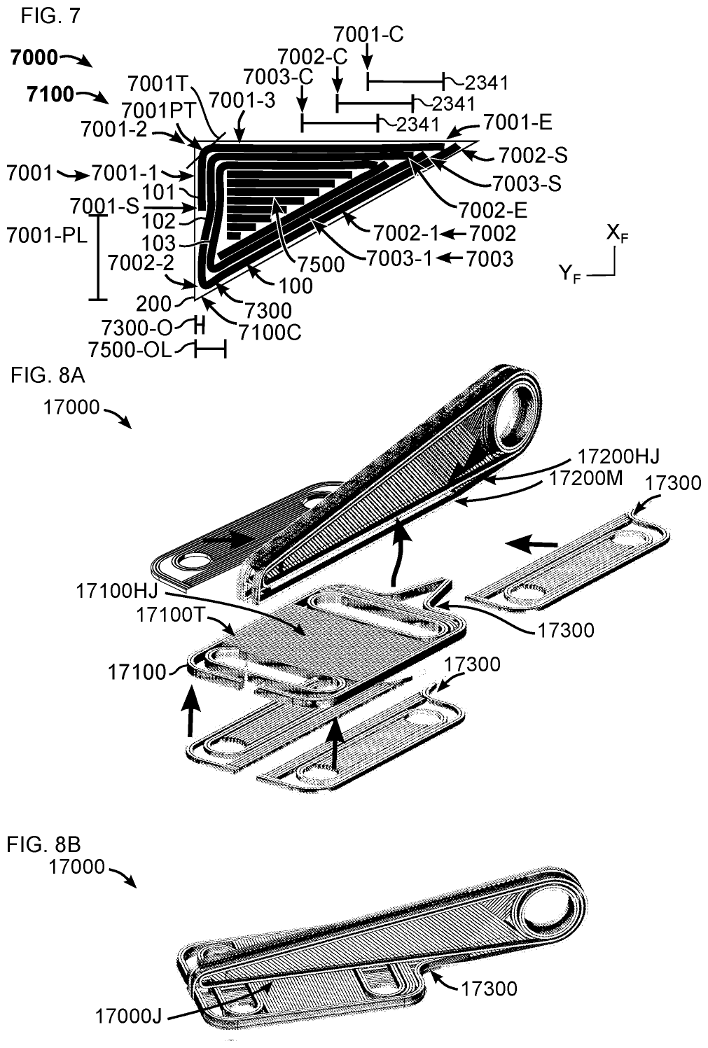

FIG. 7 is a top view of an object 7000 comprising a layer of tows 7100 comprising a plurality of fiber tow segments 101, 102, 103. For example, a method for manufacturing object 7000 comprises one or more of translating and rotating the pressure foot device 1100 along a path 7001, 7002, 7003 from a path start 7001-S, 7002-S, 7003-S to a path end 7001-E, 7002-E, wherein the straight foot segment 1110 is collinear with a tangent 7001T to the path of the pressure foot device 1100 and the point of tangency 7001PT to the path 7001 is comprised within the groove midplane 1130MP. For example, the method comprises simultaneous translation and rotation. A method to form a spiral path 7300 comprises forming one or more path, for example successively arranged paths 7001, 7002, 7003, that form a spiral arrangement. For example, the method comprises forming an internal region 7500, also called an infill 7500, that fills the area or volume, for example in a plurality of stacked rows or layers 7100, comprised within one or more of the external contour formed by the path 7001, 7002, 7003 of the object 7000. For example, the instructions 15000 comprise instructions to store 6400 one or more numerical toolpath instructions 7001-S, 7001-1, 7001-2, 7001-3, 7001-E, 7002-S, 7002-1, 7002-2, 7002-E, 7003-S, 7003-1 comprising one or more of position and orientation of the pressure foot device 1100.

For example, forming one or more paths comprises forming 15054 one or more adjacently concentric spiral paths 7001, 7002, 7003. For example, an adjacently concentric spiral comprises a spiral path comprising one or more tows that are adjacent along their longitudinal side. For example, a tow in a spiral path is longitudinally adjacent to itself upon completing one or more loops. In some embodiments, a filler, for example comprising a thermoplastic material, is formed between the tows forming the loops of the spiral path 7001, 7002, 7003.

For example, forming one or more paths comprises forming 15056 one or more concentric contour paths 100PC, 10201, 10202, 10203, 10204, 10205 that follow at least a portion of a contour 10200C of one or more of the one or more surface-based component models. For example, forming one or more paths comprises forming 15058 one or more contour paths at one or more offsets 7300-0 from a contour 7100C of one or more of the one or more surface-based component models.

For example, the method comprises acquiring 15060 path instructions comprised in a path pattern library 4121. For example, the path pattern library 4121 comprises forming one or more of: a rectangular path pattern; a rounded rectangular path pattern 10504; a circular path pattern 10502; and a figure of eight path pattern. For example, forming one or more paths comprises forming 15062 one or more path patterns 10502, 10504 selected from a path pattern library 4121.

For example, forming one or more paths comprises defining 15064 one or more regions of interest 16108 comprising one or more dimensions X, Y, Z and wherein the one or more regions of interest are highlighted on a computer display 4132 comprising, for example, a user interface 4130, presenting one or more views 16001 of the surface-based components. For example, forming one or more paths comprises forming 15066 one or more path patterns selected from a path pattern library at one or more offsets 16110 from the one or more regions of interest 16108.

For example, the method comprises acquiring a digital model of the object to be manufactured comprises storing in computer memory forbidden regions wherein the forming of paths comprising one or more elongate fiber tow models is excluded. For example, the method comprises highlighting, on a computer display presenting one or more views of the surface-based components, one or more of the forbidden regions. For example, the acquired digital model of the object to be manufactured comprises designated forbidden regions wherein the forming of paths comprising one or more elongate fiber tow models is excluded.

For example, forming of one or more paths comprising one or more elongate fiber tow models comprises a lower limit on the tow length. For example, forming one or more paths comprising one or more elongate fiber tow models comprises instructions to read from memory a lower limit on the tow length. For example, the method comprises highlighting, on a computer display presenting one or more views of: one or more of the surface-based components; one or more of the paths; and one or more of the elongate fiber tow models; wherein one or more of the elongate fiber tows the length of which is less than the lower limit on the tow length.

For example, forming one or more paths comprising one or more elongate fiber tow models comprises reading from a computer memory a lower limit on the radius of curvature of the paths wherein a fiber tow follows the path continuously. For example, the method comprises highlighting, on a computer display presenting one or more views of the surface-based components, one or more of the tow paths wherein the radius of curvature is lower than the radius of curvature lower limit stored in memory.

For example, forming one or more paths comprising one or more elongate fiber tow models comprises instructions to store in memory the tow twist at one or more locations along the path. For example, the method comprises highlighting, on a computer display presenting one or more views of the surface-based components, one or more of the tow paths wherein the tow twist is greater than a tow twist threshold stored in memory.

For example, forming of one or more paths comprising one or more elongate fiber tow models comprises a lower limit on the radius of curvature of the paths wherein a fiber tow follows the path continuously. For example, forming of one or more paths comprising one or more elongate fiber tow models comprises recording the tow twist at one or more locations along the path. For example, forming of one or more paths comprising one or more elongate fiber tow models comprises forming a discontinuity in the fiber tow at one or more locations in the path comprising a radius of curvature that is less than a lower limit. For example, forming of one or more paths comprises actuating a tow cutter 2300.

For example, forming of one or more paths comprising one or more elongate fiber tow models comprises forming one or more dimensional values of tow-free space enclosed by one or more paths. For example, the one or more dimensional values of tow-free space are estimated, for example using a computation on a processor, in 2 or 3 dimensions. For example, an alarm is raised, for example visually on a display, for example as a highlight projected onto the model, if one or more tow-free space values are greater than a predefined threshold, for example stored in memory. For example, if a value of tow-free space is greater than a tow-free space threshold value, one or more reinforcing paths are formed within the tow-free space.

For example, forming of one or more paths comprising one or more elongate fiber tow models comprises forming along the path one or more values of tow-free distance to one or more paths around one or more of the path's centerline and the path's edge. For example, if a value of tow-free distance is greater than a tow-free distance threshold value, one or more waypoints defining the one or more paths are adjusted to decrease the tow-free distance of the one or more paths. For example, if a value of tow-free distance is greater than a tow-free distance threshold value, adjusting one or more waypoints defining the one or more paths to decrease the tow-free distance of the one or more paths. For example, the method comprises highlighting, on a computer display presenting one or more views of the surface-based components, one or more of the tow paths wherein the tow-free distance is greater than a tow-free distance threshold stored in a computer memory.

For example, forming of one or more paths comprising one or more elongate fiber tow models comprises forming a plurality of parallel paths that are spaced apart by a distribution profile specified by one or more distribution components. For example, the distribution profile comprises one or more of a ramp, an ellipse, a parabola, a hyperbola, and a curve specified using a user-edited function, for example rendered visually as one or more of a two- and three-dimensional graph.

For example, segmenting the digital model comprises forming a first surface-based component 17100 comprising a first half-joint 17100HJ comprising one or more of a tenon 17100T and a mortise 17200M and forming a second surface-based component 17200 comprising a second half-joint 17200HJ matching the first half-joint 17100 and comprising one or more of a mortise 17200 and a tenon 17100. For example, segmenting the digital model comprises:

forming a first surface-based component 17100 and forming a second surface-based component 17200 that forms a joining 17000J between the first surface-based component 17100, wherein one or more of the first surface-based component 17100 and the second surface-based component 17200 comprises one or more fillets 17300 at the joining 17000J between the first surface-based component 17100 and the second surface-based component 17200. For example, segmenting the digital model comprises forming a first surface-based component and forming a second surface-based component that forms a joining 17000J between the first surface-based component at a joining region 17000J, and wherein the forming one or more path model comprises forming on the second surface-based component, at the joining region 17000J, one or more path that forms an angle of at most 80°, for example at most 60°, with a normal to the first surface-based component at the joining region 17000J.

For example, the method comprises acquiring one or more axis of symmetry in one or more of the surface-based component and dividing the one or more of the surface-based component at the one or more axis of symmetry into a plurality of component regions; and wherein the forming one or more path model comprises forming one or more first path model into a first component region of the plurality of component region and mirroring the first path model into one or more of the other component region of the plurality of component regions.

For example, the method comprises highlighting, on a computer display presenting one or more view of the surface-based component, one or more of the component region. For example, the method comprises highlighting, on a computer display presenting one or more view of the surface-based component, one or more axis of symmetry in one or more of the surface-based component.

For example, forming a three-dimensional model decomposition comprises enlarging one or more of the one or more surface-based component in one or more direction. For example, the method comprises a step of simulating a step comprising one or more of heating and compressing an assembly comprising one or more surface-based component model comprising one or more elongate fiber tow. For example, the simulating step comprises simulating a compression molding step. For example, the simulating step comprises forming one or more of a heating simulation and a compression simulation and rendering its results on a computer display. For example, the simulating step comprises estimating a decrease in size in one or more direction of one or more of the one or more surface-based component. For example, the simulating step comprises deforming one or more of the one or more surface-based component in one or more three-dimensional direction at one or more surface location. For example, the simulating step comprises forming instructions to adjust a computer-controlled compression molding process. For example, the simulating step comprises simulating a flow of infill material. For example, the simulating step comprises estimating a decrease in size in one or more dimension of one or more region comprising infill material. For example, the simulating step comprises estimating the displacement in one or more dimension of one or more path. For example, the simulating step comprises estimating the displacement in one or more dimension of one or more elongate tow. For example, the simulating step comprises highlighting, on a computer display presenting one or more view of the surface-based component, one or more region wherein a displacement of infill material is greater than an an infill displacement threshold stored in memory.

For example, rendering results on a computer display 16000 comprises rendering a three-dimensional model 16100 overlaid with one or more of a color coding, for example a color gradient, a vector field, and an animation, for example an animation of a three-dimensional model undergoing a compression molding process, representing one or more of: distribution of temperature during or after compression molding; displacement of one or more elongate tow during or after compression molding; flow of infill material during or after compression molding; and decrease in size in one or more dimension during or after compression molding. For example, the rendering provides guidance to an operator, for example by displaying one or more of a vector, a highlighting feature (a color modification, a contour), and an animation, to indicate locations on the displayed model where the operator, for example, introduces or requests from the computer-implemented method one or more elongate tow path adjustment to reduce an offset from a desired geometry or from a desired mechanical property.

For example, forming one or more path comprises forming one or more command to rotate a pressure foot device. For example, forming one or more path comprises forming one or more command to rotate a pressure foot device to an orientation angle with respect to a local tangent to the path being formed. For example, forming one or more path comprises actuating one or more pinch roller.

The disclosure also presents a system 4000 comprising: one or more computer processor 4110; and memory 4160, 4120 with executable instructions that, when executed by the one or more processor, cause the system to: receive 15010 a digital model 10100, 10200 comprising two or more spatial dimensions of an object 10000 to be manufactured; form 15020 a three-dimensional model decomposition of the object to be manufactured, wherein forming the three-dimensional model decomposition comprises segmenting 15030 at least a portion of the digital model comprising two or more spatial dimensions into one or more surface-based component 10100, 10200; and form 15040, on a surface of the one or more surface-based component model, one or more path 100P, 100PC, 10101, 10102, 10103, 10104, 10201, 10202, 10203, 10204, 10205 comprising one or more elongate fiber tow model 100, 100R, 100F, 100F2. For example, one or more of the one or more elongate fiber tow model is formed of one or more longitudinally-folded fiber tape model 100F, 100F2.

For example, the system 4000 comprises an apparatus comprising a pressure foot device 1100 comprising a channel 2400 for guiding an elongate fiber tow 100 onto an object surface 200, 10000. For example, the channel comprises a groove 1130. For example, the pressure foot device 1100 is coupled to a pressure foot device rotation driving assembly or actuator 1350, 4180. For example, the pressure foot device 1100 is comprised in a foot shaft housing 2100, characterized by a pressure foot device's axis of rotation Z, defining a Z-axis, wherein the pressure foot device's axis of rotation Z is collinear with the channel 2400 for guiding an elongate fiber tow 100 onto an object surface 10000, 10100, 10200.

For example, the system comprises a computer display 4132, 16000. For example, the system comprises a communication network 4150 connected to a system 2000 for applying an elongate fiber tow 100. For example, the system 2000 comprises one or more rangefinding detector assemblies 2600 each comprising a rangefinder 2650, one or more of the rangefinder's measurement axes ZR being oriented along a direction parallel that of the foot shaft's axis of rotation Z. The rangefinder detector 2600 is a sensor 4170 that provides, for example, data to the processor 4110 to adjust the distance of the pressure foot device 1100 with respect to the surface onto which the fiber tow 100 is applied. Data from the rangefinder 2650 therefore enables, for example. the processor to adjust the pressure that the foot applies onto the tow 100 and, for example, the width as a result of compression of the tow 100 onto the surface.

For example, the system comprises a communication network interface 4140 connected to a computer server 4200 comprising, for example, a non-volatile storage medium comprising instructions describing one or more of: one or more digital model 10100, 10200 comprising two or more spatial dimensions of one or more object 10000 to be manufactured; one or more plane-based component 10100, 10200; and one or more path 100P, 100PC, 10101, 10102, 10103, 10104, 10201, 10202, 10203, 10204, 10205. For example, one or more of the system 4000 and the computer server 4200 one or more of receive and transmit data indicating the status of the system 4000 and the state of an object being manufactured. For example, the data transmitted enables a remote operator or system to remotely monitor the progress of a manufacturing task. For example, the data transmitted is presented as an overlay on a displayed rendering of a digital model 10100, 10200. For example, the data transmitted comprises one or more of: position and orientation of the pressure foot device 1100, for example with respect to the digital model 10100, 10200; pressure foot device temperature, for example measured by one or more temperature sensor 4170; length of path deposited versus total path length; time spent depositing tow 100; estimated time remaining to deposit tow, for example computed as a function of one or more of remaining tow length to deposit, number of curved paths, and average radius of curvature of the curved paths.

The disclosure also presents a non-transitory computer-readable storage medium 4120 comprising executable instructions that, when executed by one or more processor 4110 of a computer system, cause the computer system to at least: acquire 15010 a digital model 10100, 10200 comprising two or more spatial dimensions of an object 10000 to be manufactured; form 15020 a three-dimensional model decomposition of the object to be manufactured, wherein forming the three-dimensional model decomposition comprises segmenting 15030 at least a portion of the digital model comprising two or more spatial dimensions into one or more surface-based component 10100, 10200; and form 15040, on a surface of the one or more surface-based component model, one or more path 100P, 100PC, 10101, 10102, 10103, 10104, 10201, 10202, 10203, 10204, 10205 comprising one or more elongate fiber tow model 100.

For example, the instructions to form one or more path further comprise instructions to execute one or more of forming, loading, and storing into memory one or more elongate fiber tow model 100 formed of one or more longitudinally-folded fiber tape model 100F, 100F2. For example, the elongate fiber tow model 100 is a digital model, for example comprised in a digital library, for example stored on a non-transitory computer-readable storage medium 4120. For example, one or more of the one or more elongate fiber tow model comprises a rectangular cross-section. For example, one or more of the one or more elongate fiber tow model comprises a width comprised in a range from 0.2 mm to 4 mm, for example from 0.4 mm to 2 mm. For example, one or more of the one or more elongate fiber tow model further comprises a height comprised in a range from 0.03 mm to 0.5 mm, for example from 0.12 mm to 0.25 mm.

For example, the instructions to form one or more paths comprises instructions to form one or more concentric paths 100PC, 10201, 10202, 10203, 10204, 10205 that are concentrically adjacent to each other. For example, the instructions to form one or more paths comprise instructions to: form one or more contour paths 100P, 100PC, 10101, 10102, 10103, 10104, 10201, 10202, 10203, 10204, 10205 that follow at least a portion of a contour 10100C, 10200C of one or more of the one or more surface-based component model 10100, 10200; and form a first layer 16010L comprising a first plurality of parallel paths 16010P and form a second layer 16020L comprising a second plurality of parallel paths 16020P, wherein the second layer 16020L overlaps the first layer 16010L and the paths 16020P in the second layer 16020L are orthogonal to the paths 16010P in the first layer 16010L; and wherein the area covered by the first layer and the second layer is at least partially bounded by the one or more contour path. For example, the instructions to form one or more path comprise instructions to acquire a value for a number of layers of paths to form. For example, the instructions to form one or more path comprise instructions to acquire a value for a number of coplanar adjacent paths to form. For example, the instructions to form one or more path comprise instructions for adjusting a spread 16112 of two or more coplanar adjacent paths to form.

For example, the instructions to form one or more paths comprise instructions to acquire a value for adjusting a spread 16112 of two or more coplanar adjacent paths to form over a selected region comprising one or more dimension. For example, the instructions to form one or more path comprise instructions to acquire a value for a minimum longitudinal tow extremity offset 7300-O from a surface-based component's contour 7100C.

For example, the instructions to form one or more paths comprise instructions to actuate a tow cutter (not visible in FIG. 2A), for example via actuating a tow cutter motor 2350, as a function of one or more of a minimum tow extremity longitudinal offset 7500-OL from a surface-based component's contour 7100C, a path extremity longitudinal distance 7001-PL from a surface-based component's contour, and a lower limit on the tow length.

For example, the instructions to form one or more path comprise instructions to form one or more adjacently concentric spiral path 7001, 7002, 7003. For example, an adjacently concentric spiral path is a spiral path wherein the separation of the path forming incremental revolutions of the spiral remains constant. For example, the instructions to form one or more path comprise instructions to form one or more concentric contour path 10101, 10102, 10103, 10104, 10201, 10202, 10203, 10204, 10205, 7001, 7002, 7003 that follow at least a portion of a contour of one or more of the one or more surface-based component model 10100, 10200, 7000. For example, the instructions to form one or more path comprise instructions to form one or more contour path 7001, 7002, 7003 at one or more offset 7300-O specified in one or more direction from a contour 7100C of one or more of the one or more surface-based component model 10100, 10200, 7000.

For example, the instructions further comprise instructions to acquire path instructions comprised in a path pattern library. For example the path pattern library is stored on a non-volatile storage medium 4120. For example, the instructions comprised in the path pattern library comprise instructions to form one or more of: a rectangular path; a rounded rectangular path; a triangular path; a rounded triangular path; a circular path; and a figure of eight path 7801. For example, the instructions to form one or more paths comprise instructions to form one or more path pattern selected from a path pattern library 4121. For example, the instructions to form one or more paths comprise instructions to form one or more portion of a path pattern selected from the path pattern library.

For example, the instructions to form one or more paths comprise instructions to define one or more region of interest comprising one or more dimension and wherein the one or more region of interest 16108 is highlighted on a computer display presenting one or more view of the surface-based component. For example, the instructions to form one or more path comprise instructions to form one or more path pattern selected from a path pattern library 4121 at one or more offset 7300-O from the one or more region of interest 16108.

For example, the instructions to acquire a digital model of the object to be manufactured comprise instructions to store in memory 4160 one or more forbidden region 16030 wherein the forming of paths comprising one or more elongate fiber tow model is excluded. For example, the instructions to acquire a digital model of the object to be manufactured comprise instructions to highlight, on a computer display presenting one or more view of the surface-based components, one or more of the forbidden region 16030.

For example, the instructions to form one or more path comprising one or more elongate fiber tow model comprise instructions to read from memory 4160 a lower limit on the tow length. For example, the instructions comprise instructions to highlight, on a computer display presenting one or more view of: one or more of the surface-based components; one or more of the paths; and one or more of the elongate fiber tow models; wherein one or more of the elongate fiber tows the length of which is less than the lower limit on the tow length.

For example, highlighting comprises displaying using one or more different line color, different line thickness, different transparency, different background, and different animation. Based on the visual highlighting cue, an operator decides, for example, to adjust a design. For example, a design is adjusted manually. For example, a design is adjusted by selecting an algorithmic operator comprised in the instructions to form one or more path pattern. For example, the algorithmic operator comprises instructions to form a pattern conferring one or more of mechanical and appearance properties.

For example, the instructions to form one or more path comprising one or more elongate fiber tow model comprise instructions to read from memory a lower limit on the radius of curvature of the paths wherein a fiber tow follows the path continuously. For example, the instructions comprise instructions to highlight, on a computer display presenting one or more view of the surface-based components, one or more of the tow path wherein the radius of curvature is lower than the radius of curvature lower limit stored in memory 4160, 4120.

For example, the instructions to form one or more path comprising one or more elongate fiber tow model comprise instructions to store in memory the tow twist at one or more location along the path. For example the instructions comprise instructions to highlight, on a computer display presenting one or more views of the surface-based components, one or more of the tow paths wherein the tow twist is greater than a tow twist threshold stored in memory 4160, 4120.

For example, the instructions to form one or more path comprising one or more elongate fiber tow model comprise instructions to form a discontinuity in the fiber tow at one or more location in the path comprising a radius of curvature that is less than a lower limit. For example, the instructions to form one or more path comprise instructions to actuate a tow cutter 2300, for example via a tow cutter motor 2350. For example, the cut is commanded upon reaching a cut position 7001-C, 7002-C, 7003-C to form a complete cut across the entirety of the tow's cross-section.

For example, the instructions to form one or more path comprising one or more elongate fiber tow models comprise instructions to form one or more dimensional value of tow-free space enclosed by one or more path. For example, the instructions comprise instructions wherein if a value of tow-free space is greater than a tow-free space threshold value, for example by raising an alarm, for example one or more of a visual and a haptic alarm, instructions are provided to form one or more reinforcing path within the tow-free space. For example, tow-free space is a convex area (two-dimensional space) or volume (three-dimensional space) where no tow is comprised. For example, if a value of tow-free space is greater than a threshold, structural integrity of a structure, for example deformation beyond a threshold, is compromised under load, for example a simulated load. For example, the computer-based monitoring of tow-free space with respect to a threshold provides a method to guide an operator to add one or more reinforcing tow structure one or more of within and around the tow-free space.

For example, the instructions to form one or more path comprising one or more elongate fiber tow models comprise instructions to form along the path and store in memory one or more value of tow-free distance to one or more path around one or more of the path's centerline and the path's edge. For example, a path's centerline is the set of points along the centerline of a tow, for example after the tow has been pressed by a pressure foot device 1100. For example the elongate fiber tow model comprises instructions to model the pressing of the tow by the pressure foot device. For example, around the centerline or edge means one or more direction orthogonal to the centerline or edge, respectively. For example, the instructions comprise instructions wherein if a value of tow-free distance is greater than a tow-free distance threshold value, instructions are provided to adjust one or more waypoint defining the one or more path to decrease the tow-free distance of the one or more path. For example, the instructions comprise instructions to highlight, on a computer display presenting one or more view of the surface-based components, one or more of the tow paths wherein the tow-free distance is greater than a tow-free distance threshold stored in memory 4160, 4120.

For example, the instructions to form one or more path comprising one or more elongate fiber tow model comprise instructions to form a plurality of parallel paths that are spaced apart by a distribution profile specified by reading from memory 4160, 4120 one or more distribution component. For example, a distribution profile specifies the distance separating the centerline of a first path from the centerline of a second adjacent path, for example parallel to the first path. For example, a distribution profile specifies a progression of separation distances between a plurality of paths. For example, a distribution profile is presented as a two dimensional plot with number of first to n-th path in abscissa and distance from first path in ordinates. For example, a ramp represents constant separation between a plurality of sequentially adjacent paths. For example a parabola represents increasing separation with the number of the path within the plurality of sequentially adjacent paths.

For example, the instructions to segment 15030 the digital model 1700 comprise instructions to form a first surface-based component 17100 comprising a first half-joint 17100HJ comprising one or more of a tenon 17100T and a mortise 17200M and to form a second surface-based component 17200 comprising a second half-joint 17200HJ matching the first half-joint 17100 and comprising one or more of a mortise 17200 and a tenon 17100. For example, instructions to segment 15030 the digital model 17000 comprise instructions to form a first surface-based component and to form a second surface-based component that forms a joining 17000J between the first surface-based component and the second surface-based component, wherein one or more of the first surface-based component and the second surface-based component comprises one or more fillet at the joining 17000J between the first surface-based component and the second surface-based component. For example, the instructions to segment 15030 the digital model 17000 comprise instructions to form a first surface-based component and form a second surface-based component that forms a joining 17000J between the first surface-based component and the second surface-based component at a joining region 17000J, and wherein the instructions to form one or more path model comprise instructions to form on the second surface-based component, at the joining region 17000J, one or more path that forms an angle of at most 80°, for example at most 60°, with a normal to the first surface-based component at the joining region 17000J.

For example, the instructions comprise instructions to acquire one or more axis of symmetry in one or more of the surface-based components and to divide the one or more of the surface-based components at the one or more axis of symmetry into a plurality of component regions; and wherein the instructions to form one or more path model comprises instructions to form one or more first path model into a first component region of the plurality of component regions and instructions to mirror the first path model into one or more of the other component regions of the plurality of component regions. For example the instructions comprise instructions to highlight, on a computer display presenting one or more views of the surface-based components, one or more of the component regions.

For example, the instructions comprise instructions to highlight, on a computer display presenting one or more views of the surface-based component, one or more axis of symmetry in one or more of the surface-based component.

For example, the instructions to form a three-dimensional model decomposition comprise instructions to enlarge one or more of the one or more surface-based component in one or more direction.

For example, the instructions comprise instructions to simulate a step comprising one or more of heating and compressing an assembly comprising one or more surface-based component model comprising one or more elongate fiber tow. For example, the instructions for the simulation step comprise instructions to estimate a decrease in size in one or more direction of one or more of the one or more surface-based components. For example, the instructions for the simulation step comprise instructions to deform one or more of the one or more surface-based components in one or more three-dimensional direction at one or more surface location. For example, the instructions for the simulation step comprise forming instructions to adjust a computer-controlled compression molding process. For example, the instructions to adjust a computer-controlled compression molding process comprise instructions to adjust one or more of compression rate and compression temperature. For example, the instructions for the simulation step comprise instructions to simulate a flow of infill material. For example, the instructions for the simulation step comprise instructions to estimate a decrease in size in one or more dimensions of one or more regions comprising infill material. For example, the instructions for the simulation step comprise instructions to estimate the displacement in one or more dimension of one or more path. For example, the instructions for the simulation step comprise instructions to estimate the displacement in one or more dimension of one or more elongate tow. For example, the instructions comprise instructions to highlight, on a computer display presenting one or more view of the surface-based components, one or more region wherein a displacement of infill material is greater than an an infill displacement threshold stored in memory 4160, 4120.

For example, the instructions to form one or more paths comprise instructions to form one or more command to rotate a pressure foot device 1100, for example via a foot rotation motor 1350 coupled to the pressure foot device 1100. For example, the instructions to form one or more path comprise instructions to form one or more command to rotate the pressure foot device 1100 to an orientation angle with respect to a local tangent 7001T to the path 7001PT being formed. For example, the instructions to form one or more path comprise instructions to actuate one or more pinch roller or pinch roller motor 2550, for example comprised in a one or more pinch roller assembly 2500, for example a pinch roller driving the output speed of the tow 100 from the system 2000 for applying an elongate fiber tow 100.

1-126. (canceled)

127. A computer-implemented method for modelling and forming a fiber-reinforced plastic composite object comprising one or more fiber tows, comprising:
acquiring a digital model comprising two or more spatial dimensions of an object to be manufactured;
forming a three-dimensional model decomposition of the object to be manufactured, wherein forming the three-dimensional model decomposition comprises segmenting at least a portion of the digital model comprising two or more spatial dimensions into one or more surface-based component models;
reading from a computer memory a lower limit on a radius of curvature of a path of the one or more surface-based component models, wherein a fiber tow follows the one or more paths continuously, and storing in memory a tow twist at one or more locations along the one or more paths;
highlighting, on a computer display presenting one or more views of the surface-based component models, the one or more paths, wherein the radius of curvature is lower than the radius of the lower limit; and
forming, on a surface of the one or more surface-based component models, the one or more paths, each comprising one or more elongate fiber tow models.

128. The method of claim 127, wherein forming one or more path comprises adjusting a spread of two or more coplanar adjacent paths to form.

129. The method of claim 127, wherein forming one or more path comprises forming one or more set of adjacently concentric spiral paths.

130. The method of claim 127, wherein forming one or more path comprises forming one or more set of concentric contour paths that follow at least a portion of a contour of one or more of the one or more surface-based component model.

131. The method of claim 127, further comprising acquiring path instructions comprised in a path pattern library.

132. The method of claim 127, further comprising highlighting, on a computer display presenting one or more view of the surface-based components, one or more of forbidden region.

133. The method of claim 127, wherein forming one or more path comprising one or more elongate fiber tow model comprises instructions to read from memory a lower limit on the tow length; and highlighting, on a computer display presenting one or more view of:
one or more of the surface-based components;
one or more of the paths; and
one or more of the elongate fiber tow models;
wherein one or more of the elongate fiber tows the length of which is less than the lower limit on the tow length.

134. The method of claim 127, further comprising highlighting, on a computer display presenting one or more view of the surface-based components, one or more of the tow paths wherein the tow twist is greater than a tow twist threshold stored in memory.

135. The method of claim 127, wherein the forming of one or more path comprising one or more elongate fiber tow model comprises forming a discontinuity in the fiber tow at one or more locations in the path comprising a radius of curvature that is less than a lower limit.

136. The method of claim 127, wherein the forming of one or more path comprising one or more elongate fiber tow model comprises forming a plurality of parallel paths that are spaced apart by a distribution profile specified by one or more distribution component.

137. The method of claim 127, further comprising:
acquiring one or more axis of symmetry in one or more of the surface-based components;
dividing the one or more of the surface-based components at the one or more axis of symmetry into a plurality of component regions; and
wherein the forming one or more path model comprises forming one or more first path model into a first component region of the plurality of component regions and mirroring the first path model into one or more of the other component regions of the plurality of component regions.

138. The method of claim 127, further comprising highlighting, on a computer display presenting one or more views of the surface-based components, one or more axes of symmetry in one or more of the surface-based components.

139. The method of claim 127, further comprising highlighting, on a computer display presenting one or more view of the surface-based components, one or more region wherein a displacement of infill material is greater than an an infill displacement threshold stored in memory.

140. A system comprising:
one or more computer processors; and
memory with executable instructions that, when executed by the one or more processors, cause the system to:
receive a digital model comprising two or more spatial dimensions of an object to be manufactured;
form a three-dimensional model decomposition of the object to be manufactured, wherein forming the three-dimensional model decomposition comprises segmenting at least a portion of the digital model comprising two or more spatial dimensions into one or more surface-based components;
highlight, on a computer display presenting one or more view of the surface-based components, one or more of the tow path wherein the radius of curvature is lower than the radius of curvature lower limit stored in memory; and
form, on a surface of the one or more surface-based component models, one or more paths comprising one or more elongate fiber tow models, wherein forming the one or more path comprises reading from a computer memory a lower limit on the radius of curvature of the path wherein a fiber tow follows the path continuously, and storing in memory the tow twist at one or more location along the path.

141. The system of claim 140, wherein the pressure foot device is coupled to a pressure foot device rotation actuator.

142. The system of claim 140, wherein the pressure foot device is comprised in a foot shaft housing, characterized by a pressure foot device's axis of rotation, defining a Z-axis, wherein the pressure foot device's axis of rotation is collinear with the channel for guiding an elongate fiber tow onto an object surface.

143. The system of claim 140, further comprising a communication network connected to a system for applying an elongate fiber tow.

144. A non-transitory computer-readable storage medium comprising executable instructions that, when executed by one or more processors of a computer system, cause the computer system to at least:
acquire a digital model comprising two or more spatial dimensions of an object to be manufactured;
form a three-dimensional model decomposition of the object to be manufactured, wherein forming the three-dimensional model decomposition comprises segmenting at least a portion of the digital model comprising two or more spatial dimensions into one or more surface-based components;
highlight, on a computer display presenting one or more view of the surface-based components, one or more of the tow path wherein the radius of curvature is lower than the radius of curvature lower limit stored in memory; and
form, on a surface of the one or more surface-based component models, one or more paths comprising one or more elongate fiber tow models, wherein forming the one or more path comprises reading from a computer memory a lower limit on the radius of curvature of the path wherein a fiber tow follows the path continuously, and storing in memory the tow twist at one or more location along the path.

145. The non-transitory computer-readable storage medium of claim 144, wherein the instructions to form one or more path comprise instructions for adjusting a spread of two or more coplanar adjacent paths to form.

146. The non-transitory computer-readable storage medium of claim 144, wherein the instructions to form one or more path comprise instructions to form one or more adjacently concentric spiral path.
